(19) United States
(12) Patent Application Publication
(10) Pub. No.: US 2013/0058505 A1
(43) Pub. Date: Mar. 7, 2013

(54) CIRCULAR LOUDSPEAKER ARRAY WITH CONTROLLABLE DIRECTIVITY

(71) Applicants: Gert Kudahl Munch, Hjerm (DK); Jakob Dyreby, Struer (DK); Martin Olsen, Struer (DK); Martin Bo Møller, Struer (DK)

(72) Inventors: Gert Kudahl Munch, Hjerm (DK); Jakob Dyreby, Struer (DK); Martin Olsen, Struer (DK); Martin Bo Møller, Struer (DK)

(73) Assignee: BANG & OLUFSEN A/S, Struer (DK)

(21) Appl. No.: 13/697,040

(22) PCT Filed: May 10, 2011
(86) PCT No.: PCT/EP11/57532

§ 371 Date: Nov. 9, 2012

(30) Foreign Application Priority Data
May 21, 2010 (DK) PA 2010 00446

(51) Int. Cl. H03F 99/00

(52) U.S. Cl. 381/120

(57) ABSTRACT

The invention relates to a sound-emitting device with controllable directivity comprising a plurality of sound sources (7) distributed over the surface of a body 5, each of said sound sources (7) being driven by a separate power amplifier (12), the input terminal of which is provided with the output signal from a corresponding filter (10), such that the frequency response of each individual sound source (7) can be controlled, where each filter (10) is provided with an input signal (11) corresponding to a plurality of input channels Ch₁, Ch₂ . . . Ch_{N}. The body (5) could according to one embodiment of the invention comprise a cylindrical body provided with end pieces (6) at either longitudinal end. The present invention furthermore relates to a method for controlling the individual sound sources of the sound-emitting device in order to obtain a given target directivity.

### TECHNICAL FIELD

The present invention relates generally to the field of loudspeakers and more specifically to means of controlling the directional characteristics of loudspeakers. Still more specifically, the present invention relates to the application of acoustic beamforming for controlling the directional characteristics of a loudspeaker unit comprising a plurality of individual loudspeaker drivers distributed over a surface.

### BACKGROUND OF THE INVENTION

The directivity of loudspeakers has been subject to extensive consideration among loudspeaker designers over the years. The general consensus appears to be that investigation of the correlation between loudspeaker directivity and various perceptual aspects may be of great importance in the development of future innovative sound systems. Recently, a literature study of the topic was presented by Evans et al. Based on a literature review concerning the optimal directivity for stereo reproduction, loudspeaker directivity control and previous investigations into the influence of directivity upon listeners, the inventors found that results from previous studies do not provide definite evidence for relationships between directivity type and the perceptual attribute under investigation. This is caused by the multiple kinds of loudspeakers used in the experiments, as sources with different directivity. It is apparent that this will introduce the risk of judging other parameters than directivity due to inherent differences in the individual loudspeaker types. It would consequently be advantageous to have access to a single loudspeaker or loudspeaker unit, the directional characteristics of which can be varied without affecting other parameters of the loudspeaker unit.

### SUMMARY OF THE INVENTION

According to the invention there is provided a loudspeaker unit which offers an extended range of loudspeaker directivities. The loudspeaker unit according to the present invention implements controllable directivity, thereby providing a foundation for achieving supportive listening test data in future experimental investigations.

According to the invention there is provided a loudspeaker unit comprising a uniform circular array of loudspeaker drivers for broadband audio reproduction by means of acoustic beamforming. The loudspeaker unit according to the invention complies with a series of specifications and requirements valid for free field conditions: The beam pattern must be steerable to a certain focus direction in the horizontal plane (0-360°) and the beam width should be variable from an omni-directional to a narrow beam characteristic. Due to the fact that ideal conditions will not be ideally met in practice, side lobes (or secondary lobes) might be formed outside the main lobe direction. From a practical point of view, a side lobe level of −20 dB relative to the main lobe may be acceptable, but other—also more stringent—requirements may also be specified. Furthermore, the physical dimensions should be minimized in order to reduce room interaction. In the detailed description of the invention, a given target function will be implemented that satisfies frequency invariance in the frequency range 500 Hz to 4 kHz. The detailed description comprises both simulated directivity patterns obtained according to the teachings of the present invention and measured results from a real prototype loudspeaker unit, measured in an anechoic room.

Within the theory of beamforming, two concepts are often considered regarding the beamformer-weighting of the signals for each array element of the beamformer, when controlling a circular array: (1) Phase compensation and amplitude tapering, and (2) the concept of phase modes. The first method concerns optimizing beam pattern characteristics (e.g. half-power bandwidth of the main lobe and minimizing side lobe levels), while advantage is taken of the inherent circular periodicity using method (2).

In this specification, the directivity is defined as the ratio of the position dependent frequency response to the frequency response of a reference position. The directivity is evaluated only in the horizontal plane. The orientation is expressed in cylindrical coordinates and the directivity is given by the expression:

$$D ( f , r , ϕ ) = 20 {log}_{10} \frac{G ( f , r , ϕ )}{G ( f , {r}_{ref} , {ϕ}_{ref} )} \qquad ( 1 )$$

where (r_{ref}, φ_{ref}) is the direction of the beam pattern focus, or equivalently, the maximum, and G is the frequency response.

The synthesis of the desired directivity or beam pattern is based on a spatial Fourier analysis. The procedure for determining the beamformer-weight for each array element (loudspeaker driver) is (1) the desired pattern is determined based on the specific directivity target function; (2) a spatial Fourier analysis of the directivity pattern is applied, and; (3) the weights are determined by the resulting Fourier coefficients and the sound field transfer function (from each element to a given observation point).

Theory

The following paragraphs briefly present the most important theory relevant for the present invention. The derivation of the sound field generated from a line source located on an infinitely long cylinder is outlined. The results of this derivation are later utilized as the transfer function applied in the present invention and for simulations of the resulting directivity characteristics. The presented theory winds up with a description of the method of the directivity pattern synthesis applied in the present invention: the concept of phase modes.

Line Source on a Cylinder

Referring to FIG. 2 of this specification, the sound field generated by a general cylindrical source as a general outgoing wave is given by the expression:

$$p ( r , ϕ ) = {\sum }_{m = 0}^{∞} {A}_{m} cos ( m ϕ ) {H}_{m}^{( 2 )} ( k r ) {e}^{j ω t} \qquad ( 2 )$$

The meaning of the symbols used in FIG. 2 and in the above expression is:
α [symbol] cylinder radius;
dα [symbol] width of line source located on the cylinder;
k [symbol] wavenumber;
r, φ [symbol] cylindrical coordinates of observation point;
Hₘ⁽²⁾ [symbol] cylindrical Hankel function of second kind;
Aₘ [symbol] strength of each mode comprising p(r, φ).

Of special interest is the corresponding radial particle velocity of the surface:

$${u}_{r} ( a , ϕ ) = \frac{j}{ωρ} \frac{\partial p}{\partial r} {\vert}_{r = a} = [ \frac{{A}_{0} {E}_{0}}{2 ρ c} + {\sum }_{m = 1}^{∞} \frac{{A}_{m} {E}_{m}}{ρ c} cos ( m ϕ ) ] {e}^{jω t} \qquad ( 3 )$$

where the coefficients Eₘ are expressed by:

$${E}_{m} = j {∈}_{m} \frac{d {H}_{m}^{( 2 )} ( ka )}{d ( ka )} m = 0 , 1 , 2 , … \qquad ( 4 )$$

With ε₀=2 and εₘ=1 for m>0. In the case where only a single line element of the cylinder is vibrating (see FIG. 2), the radial velocity distribution on the cylinder surface may be described as:

$${U}_{a} ( ϕ ) = \{ \begin{matrix}{u}_{0} {e}^{j ω t} & - \frac{d α}{2} < ϕ < \frac{d α}{2} \\ 0 & + \frac{d α}{2} < ϕ < 2 π - \frac{d α}{2}\end{matrix} \qquad ( 5 )$$

with u₀ being the line source velocity and dα→0. Thus, an infinitely long and thin line source is defined on the surface of a rigid cylinder of infinite extent. The Fourier-series expansion of this function is:

$${U}_{a} ( ϕ ) = ( \frac{{u}_{0} d α}{π} ) [ \frac{1}{2} + {\sum }_{m = 1}^{∞} cos ( m ϕ ) ] {e}^{j ω t} \qquad ( 6 )$$

The boundary condition on the surface is given as uᵣ(a, φ)=uₐ(φ), which implies that the coefficients Aₘ must satisfy:

$${A}_{m} = \frac{ρ {cu}_{0} d α}{π {E}_{m}} m = 0 , 1 , 2 , … \qquad ( 7 )$$

Some examples of the sound pressure normalized with the maximum value are shown in FIG. 3. As can be seen, the cylinder has very little influence at low frequencies. At higher frequencies, the cylinder gives rise to a certain directionality.

Simulation results are based on a uniform circular array of line sources on an infinitely long cylinder. Expansion of the solution in order to simulate the sound field generated by an array can be performed. Here, the solution for N equidistant line sources is introduced by the superposition principle. A phase difference φ−φₙ in equation (2) is included in the cosine term, where

$${ϕ}_{n} = 2 π ( \frac{n}{N} ) n = 0 , 1 , 2 , … , ( N - 1 ) \qquad ( 8 )$$

Each source contributes to the sound field, and hence, summing over N contributions in (2) is required in order to obtain the complete solution.

In general, this solution introduces a number of ideal conditions, which cannot be satisfied in practice. The length of the cylinder and line sources must obviously be truncated in a practical implementation. This implies that simulations for frequencies with wavelengths comparable or larger than the truncated cylinder length may not give proper results. On the other hand, this somewhat ideal solution accounts for near field terms and allows acoustic parameters to be determined analytically at any distance from the cylinder surface.

Phase Modes

In the following, a loudspeaker producing a specific directivity pattern, H(φ, f), is considered. A specific directivity pattern, H(φ, f), is considered. This target directivity can be approximated with an array consisting of N elements, by adjusting the amplitude and phase of the individual elements with specific element weight, wₙ(f)

$$H ( ϕ , f ) \approx {\sum }_{n = 0}^{N - 1} {w}_{n} ( f ) g ( ϕ , r , {ϕ}_{n} , f ) \qquad ( 9 )$$

where g(φ, r, φₙ, f) is the transfer function from the n'th array element, with angular position φₙ, to an observation point (φ, r) as shown in FIG. 4.

Assuming a uniform circular array, consisting of arbitrary elements mounted on an arbitrary baffle geometry, the radiated directivity can be controlled using the concept of phase modes. Using this method, specific element weights are determined to adjust the array response. Making use of the circular periodicity inherent in the array configuration, the target directivity can be expanded into circular harmonics using a Fourier series representation,

$$H ( ϕ , f ) \approx {\sum }_{p = - M}^{M} {H}_{p} ( ϕ , f ) = {\sum }_{p = - M}^{M} {a}_{p} ( f ) {e}^{j ϕ p} \qquad ( 10 )$$

where M is the number of harmonics truncating the general summation from −∞ to ∞. The complex coefficient of the Fourier series expansion aₚ can be numerically determined using the discrete Fourier transform as

$${a}_{p} ( f ) = \frac{1}{N} {\sum }_{n = 0}^{N - 1} H ( {ϕ}_{n} ) {e}^{- j p \frac{2 π}{N} n} \qquad ( 11 )$$

where p is an integer and N is the total number of array elements.

FIG. 5 illustrates an example of a single directivity pattern composed of a weighted sum of the first three circular harmonics. The constants aₚ specify the strength of each harmonic needed to generate the shown directivity pattern.

In accordance with the placement of the elements in the array, the weights must be 2π periodic. Hence, the weights can be decomposed in circular harmonics:

$${w}_{n} ( f ) \approx {\sum }_{p = - M}^{M} {w}_{p} ( {ϕ}_{n} , f ) = {\sum }_{p = - M}^{M} {\hat{a}}_{p} ( f ) {e}^{j p {ϕ}_{n}} \qquad ( 12 )$$

Here, âₚ(f) denotes the Fourier coefficients of the expanded element weights (not to be confused with the corresponding coefficients of the target directivity aₚ(f)). Each harmonic of the target directivity can be determined through summation across the weighted array elements. The elements are described by the acoustic transfer function g(φ, r, φₙ, f) and weighted by the p'th harmonic of the element weights â(f)e^{jpφn}

$${H}_{p} ( ϕ , f ) \approx {\sum }_{n = 0}^{N - 1} {\hat{a}}_{p} ( f ) {e}^{j p {ϕ}_{n}} g ( ϕ , r , {ϕ}_{n} , f ) \qquad ( 13 )$$

In case of the infinite cylinder with line sources, the transfer function g(φ, r, φₙ, f) is given by (2) and (7). Besides, analytical derivations g(φ, r, φₙ, f) may also be determined through FEM simulations or measurements.

Moving the constant âₚ(f) out of the summation and applying (10) it is possible to write (13) as

$${a}_{p} ( f ) {e}^{j p ϕ} \approx {\hat{a}}_{p} ( f ) {\sum }_{n = 0}^{N - 1} g ( ϕ , r , {ϕ}_{n} , f ) {e}^{j p {ϕ}_{n}} \qquad ( 14 )$$

Rearranging the terms, it is possible to determine the unknown p'th harmonic of the specific element weights from the given harmonic of the target directivity and the obtained acoustic transfer function

$${\hat{a}}_{p} ( f ) \approx \frac{{a}_{p} ( f ) {e}^{j p ϕ}}{{\sum }_{n = 0}^{N - 1} g ( ϕ , r , {ϕ}_{n} , f ) {e}^{j p {ϕ}_{n}}} \qquad ( 15 )$$

The element weights are calculated from a summation of the M harmonics at the angle of the element angular position φₙ

$${w}_{n} ( f ) \approx {\sum }_{p = - M}^{M} {\hat{a}}_{p} ( f ) {e}^{j p {ϕ}_{n}} \qquad ( 16 )$$

Substituting the expression for âₚ into (16) the equation can be written as

$${w}_{n} ( f ) \approx {\sum }_{p = - M}^{M} \frac{{a}_{p} ( f ) {e}^{j p ϕ} {e}^{j p {ϕ}_{n}}}{{\sum }_{n = 0}^{N - 1} g ( ϕ , r , {ϕ}_{n} , f ) {e}^{j p {ϕ}_{n}}} \qquad ( 17 )$$

Here, it is seen that the term e^{jpφ} is a scaling factor, which does not change between the calculations of the specific element weights. Hence, it can be calculated for an arbitrary angle (e.g. φ=0 for simplicity).

Weighting the array elements with the calculated values results in the directivity Ĥ(φ, f), which ideally is equal to the target directivity H(φ, f)

$$\hat{H} ( ϕ , f ) = {\sum }_{n = 0}^{N - 1} {w}_{n} ( ϕ , f ) g ( ϕ , r , {ϕ}_{n} , f ) \qquad ( 18 )$$

According to a first aspect of the invention there is provided a method for controlling the directivity of a sound-emitting device, the method comprising:
(i) providing an array consisting of a plurality of sound sources each driven by an individual power amplifier;
(ii) for each of said plurality of sound sources providing a separate filter, the output signal of which is provided to the corresponding power amplifier;
(iii) at a specific frequency choosing a desired directivity;
(iv) at said specific frequency determining the directivity of each of said sound sources;
(v) at said specific frequency decomposing the desired directivity into p harmonics;
(vi) at said specific frequency decomposing the sound source directivity for each sound source of the array into p harmonics;
(vii) at said specific frequency summing the sound source contributions to the p'th harmonic of the unweighted array;
(viii) at said specific frequency calculating a weightₚ as the ratio between the desired harmonic strength and the harmonic strength of the unweighted array;
(ix) at said specific frequency calculating the source weights through a summation of harmonic weights at source positions, thereby arriving at the weights for each sound source in the array at that specific frequency where the source directivity applies;
(x) repeating the above steps (iii) through (ix) for each desired frequency of the frequency interval of interest, whereby the coefficients of each separate filter for each of the sound sources are determined;
(xi) constructing the required number of separate filters based on the coefficients determined under (x) above.

According to a second aspect of the present invention, there is provided a circular loudspeaker array with controllable directivity comprising a plurality of sound sources distributed over the surface of a body, each of the sound sources being driven by a separate power amplifier, the input terminal of which is provided with the output signal from a corresponding filter, such that the frequency response of each individual sound source can be controlled, where each filter is provided with an input signal corresponding to a plurality of input channels Ch₁, Ch₂ . . . Ch_{N}.

According to an embodiment of the invention, the sound-emitting device comprises a cylindrical body provided with end pieces at either longitudinal end.

According to an embodiment of the invention, the sound sources are uniformly distributed over a circular path on the surface of the body, specifically (but not limited hereto) over a circular path substantially in parallel with the end pieces. According to a specific embodiment of the invention, the surface of the body is substantially rigid.

According to an embodiment of the invention, each of the filters has filter characteristics that are determined according to the method defined above. Other methods of determining suitable filter characteristics may however be applied.

### BRIEF DESCRIPTION OF THE DRAWINGS

The invention will be better understood by reading the following detailed description of an embodiment of the invention and with reference to the figures of the drawing, wherein:

FIG. 1 shows four different beam patterns defined by a typical directivity target function;

FIG. 2 shows an embodiment of the invention configured as a line source located on a cylindrical baffle;

FIG. 3 shows normalized sound pressure in the far field generate by a line source on a rigid cylinder of infinite length, calculated for various values of ka: ka=0.5, ka=2, ka=8 and ka=32;

FIG. 4 shows a cross sectional view of the configuration of N line sources in a uniform circular array;

FIG. 5 shows an illustration of a directivity pattern expanded into circular harmonics with coefficients a₀=1, a₁=a₋₁=1, and a₂=a₋₂=1. (a) First harmonic p=0. (b) Second harmonic p=±1. (c) Third harmonic p=±2. (d) The resulting directivity consisting of the first three harmonics, with the stated amplitudes;

FIG. 6 shows contour plots visualizing simulation results. Distance between contours=3 dB: (a) Directivity pattern used as target for the beamforming. (b) Simulated directivity pattern, using 24 element circular array with r=0.15 m;

FIG. 7 shows a plot of the ration of the sound pressure at the focus point of the formed main lobe to the corresponding pressure arising from a single source on the cylinder;

FIG. 8 shows simulations of the directivity response including various types of error. Distance between contours=3 dB: (a) Random angular displacement of ±1°. (b) Uniform random noise 0.5 dB of transfer function from which the phase mode weights are determined. (c) Both angular displacement and transfer function error;

FIG. 9(a) shows a schematic representation of an embodiment of the invention comprising six loudspeakers:

FIG. 9(b) shows a photo of the measurement setup for the experimental study of a uniform circular array with six 2″ loudspeaker drivers in an anechoic room;

FIG. 10 shows the horizontal directivity of a small scale uniform circular array with six loudspeaker drivers. The response is normalized in accordance to (1). (a) shows the target function. In each of the remaining figures the results are shown for the measurement with simulated transfer function gₛᵢₘ ( - - - ) the measured transfer function gₘₑₐₛ ( . . . ), and the predicted directivity (−), respectively, and for five different frequencies: (b) 500 Hz (ka=0.9), (c) 700 Hz (ka=1.3), (d) 1000 Hz (ka=1.8), (e) 1400 Hz (ka=2.6), and (f) 2000 Hz (ka=3.7);

FIG. 11 shows simulated horizontal directivity with imposed errors in the array element angular position ( - . - ) and the ideal simulation (−). The measurement results obtained with measured transfer function are also shown ( . . . . ). Three different frequencies are evaluated: (a) 500 Hz, (b) 700 Hz, and (c) 1000 Hz;

FIG. 12 shows the ratio of the sound pressure at the focus point of the formed main beam by six sources and the corresponding pressure arising from a single source on the cylinder;

FIG. 13 shows a block diagram of the basic layout of the circular loudspeaker array with controllable directivity according to an embodiment of the invention comprising separate filters and power amplifiers for each individual loudspeaker driver; and

FIG. 14 illustrates the calculations performed in order to determine each individual filter characteristic of the filters shown in FIG. 13.

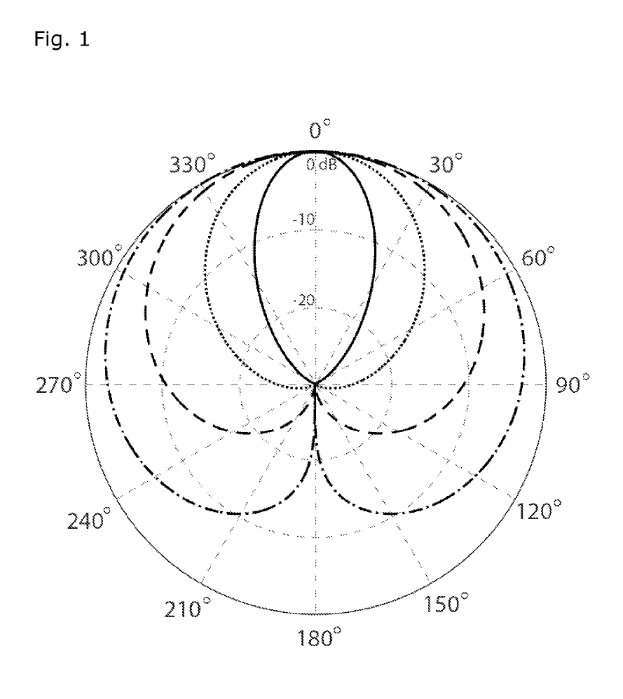

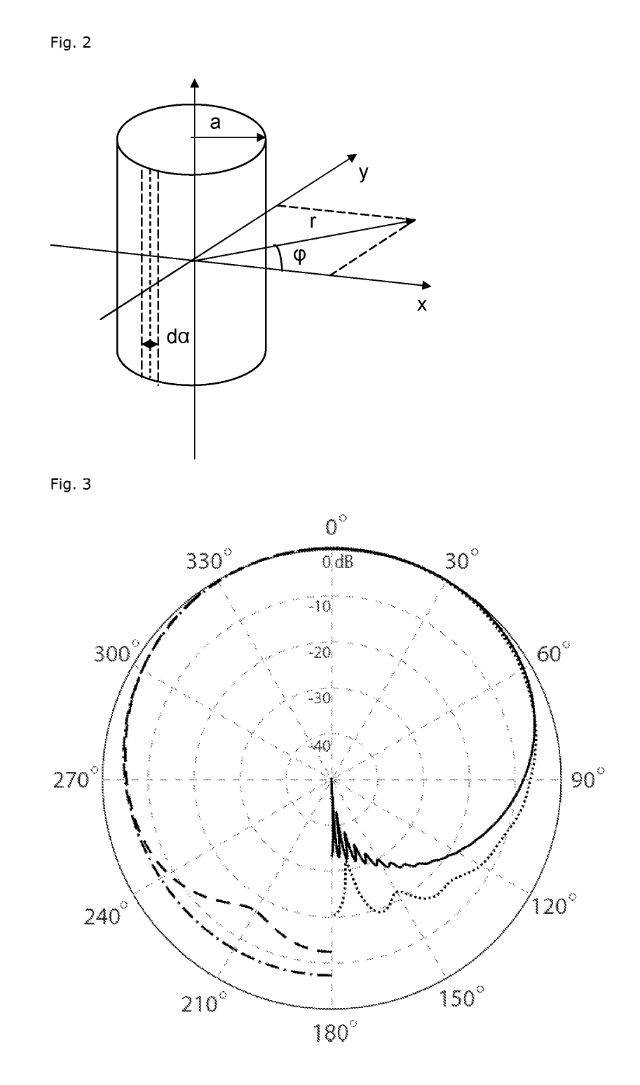

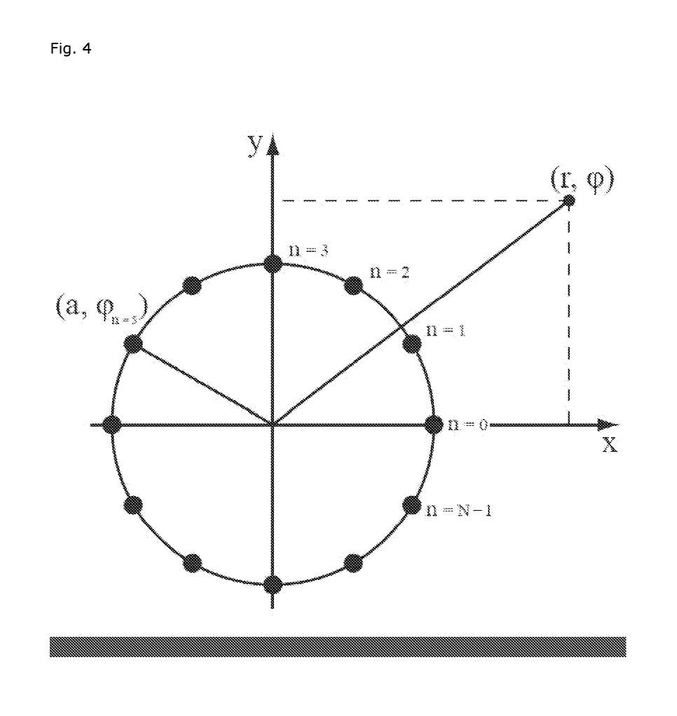

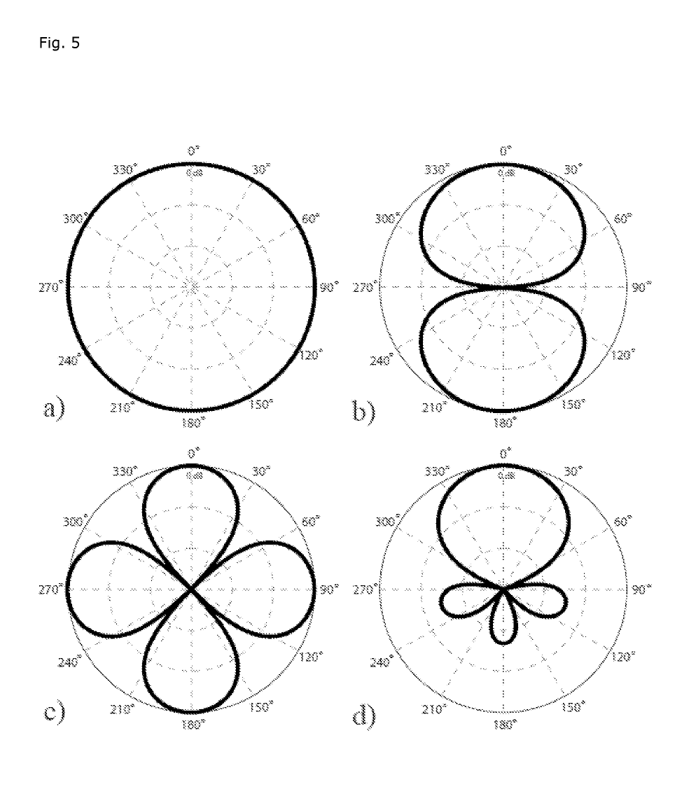

### DETAILED DESCRIPTION OF THE INVENTION

In the following, both simulated results of the application of the beamforming method of the invention and actual measurements using a simple six-loudspeaker embodiment are shown.

Simulations

The simulation results presented below were made for an infinite cylinder with equidistantly spaced line sources as outlined above. The chosen array configuration consists of 24 line sources positioned on an infinite cylinder with a=0.15 m. This combination of elements and array radius allows beamforming up to a frequency of approximately 4.3 kHz, according to the sampling criterion. The directivity pattern of the array is obtained under free field conditions, which removes otherwise disturbing reflections from the simulation. To avoid influence of near field components, the simulated directivity is determined from the sound pressure at a radial distance of r=3.5 m. Determining the directivity at a specific radial distance is possible due to the chosen derivation as presented above. The main lobe of the target directivity is oriented towards 0° and the corresponding weights applied to the array elements are calculated following the procedure described in the above section on phase modes.

Target Function

Applying the concept of phase modes to control the array makes it possible to form a large variety of directivity patterns. The chosen target directivity pattern for the simulation has the smallest beam width desired for the psychoacoustic experiments mentioned in the background of the invention. This corresponds to a beam width of 23° at 3 dB pressure attenuation (being equal to half power bandwidth assuming far field conditions). Due to the narrow beam width, this pattern is especially demanding to realize, as the transition from main lobe with high amplitude to reduced level occurs across a small angular variation. This steep slope necessitates accurate control of the array elements to facilitate such destructive interference. It is assumed that if this narrow pattern can be realized, the remaining less demanding and broader directivities can also be realized using this configuration.

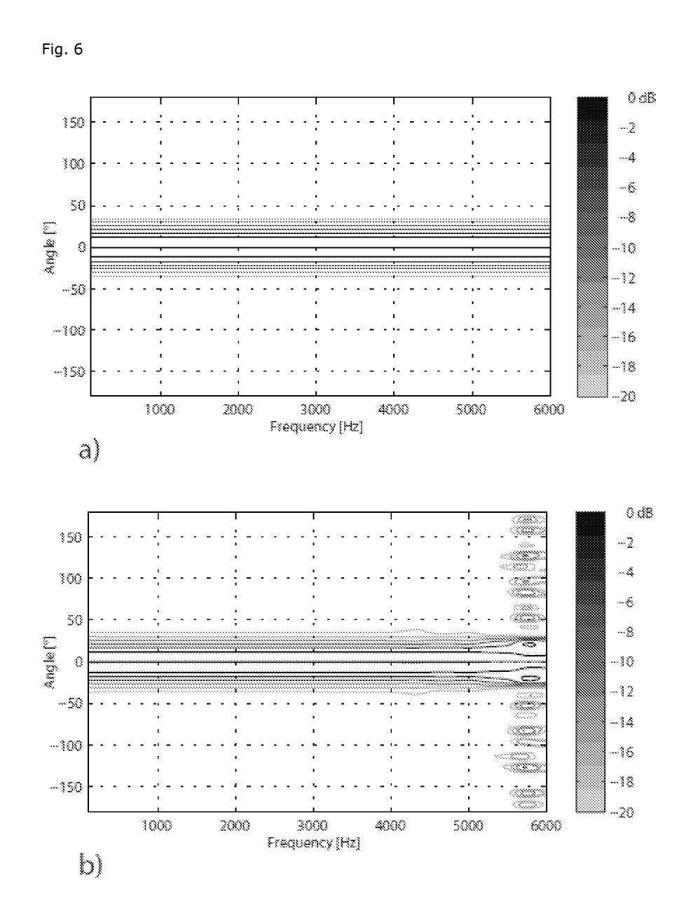

FIG. 6(a) shows a contour plot of the target directivity pattern across frequency. The target is shown for comparison purposes, and according to the used directivity definition (1), the calculated pressure is normalized with respect to the pressure in the focus direction. The straight contour lines of the target response reflect frequency invariance of the target directivity. In relation to the goals defined previously, frequency invariance is desired in the specified frequency interval of concern.

Target Function Realization

Through a simulation study it has been found that the target directivity could be formed with side lobe level below −20 dB, within the frequency range of concern, using 24 elements in the circular array. Side lobe level is here defined as the dB difference between the maximal amplitude of the main lobe and the amplitude of the side lobes. FIG. 6(b) shows the simulated directivity pattern in the frequency range 100 Hz to 6 kHz. At frequencies above the specified upper limit of 4.3 kHz, side lobes are introduced (reference numeral 1) and at 5.5 kHz the control scheme breaks down (as indicated by the series of side lobes collectively indicated by reference numeral 2). This is caused by the wavelength distance between the elements being too large to realize the desired directivity pattern, which corresponds to insufficient sampling points available in order to estimate the p'th circular harmonic. Thereby, a larger density of elements is needed in order to extend the upper frequency limit at which the desired directivity pattern can be formed.

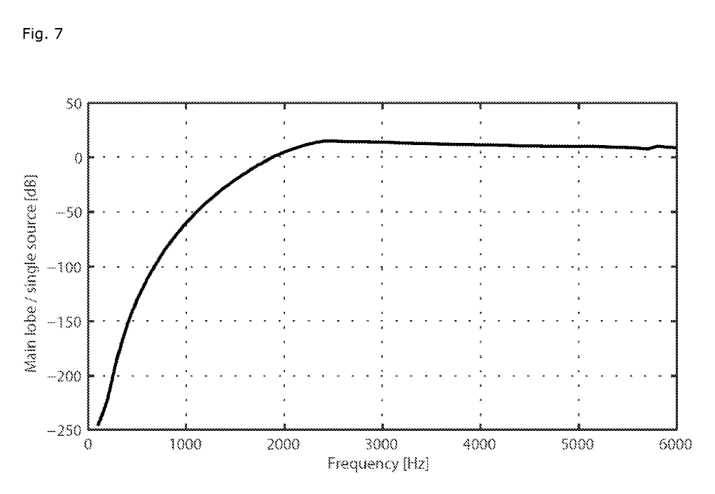

Increasing the number of elements reduces the separation distance between the individual elements, which increases both the upper and lower frequency limit. A low frequency limit is effectively introduced due to an increased sensitivity to errors in the element weights at low frequencies. This effect is caused by the inter-element wavelength distance being very small, hence the phase change in the sound pressure emitted from one source at the position of neighboring sources is accordingly small. Hereby, a large amount of destructive interference is needed to form the correct directivity pattern. The amount of destructive interference is illustrated with FIG. 7, where the amplitude pressure at the main beam of the formed directivity is compared with the corresponding amplitude pressure generated by a single line source on the cylinder. From this plot it is seen that the amount of destructive interference at low frequencies reduces the radiated sound pressure extensively. With such large attenuation it is unrealistic to realize the target directivity, as boosting the drivers by more than 100 dB is impossible without adding significant distortion or causing damage to the loudspeaker drivers. Due to the large reduction in the pressure amplitude of the formed directivity pattern, the beamforming procedure is very sensitive to errors in the element weights at low frequencies.

Introducing Errors in the Simulation

Constructing a circular array on a cylindrical baffle introduces errors in the system due to production tolerances. The main error sources arise from non-uniform angular placement of the elements and deviations in the baffle geometry compared with the ideal case. The significance of such errors can be illustrated by inclusion in the simulation of the array. The non-uniform placement of array elements is modeled by adding uniform distributed random variation to the angular position. Deviations in the baffle structure and finite approximations of the infinite cylinder and line source are modeled as a uniformly distributed random variation in the transfer function (symbolized with g(φ, r, φₙ, f) in (13)) used in the design procedure of the element weights.

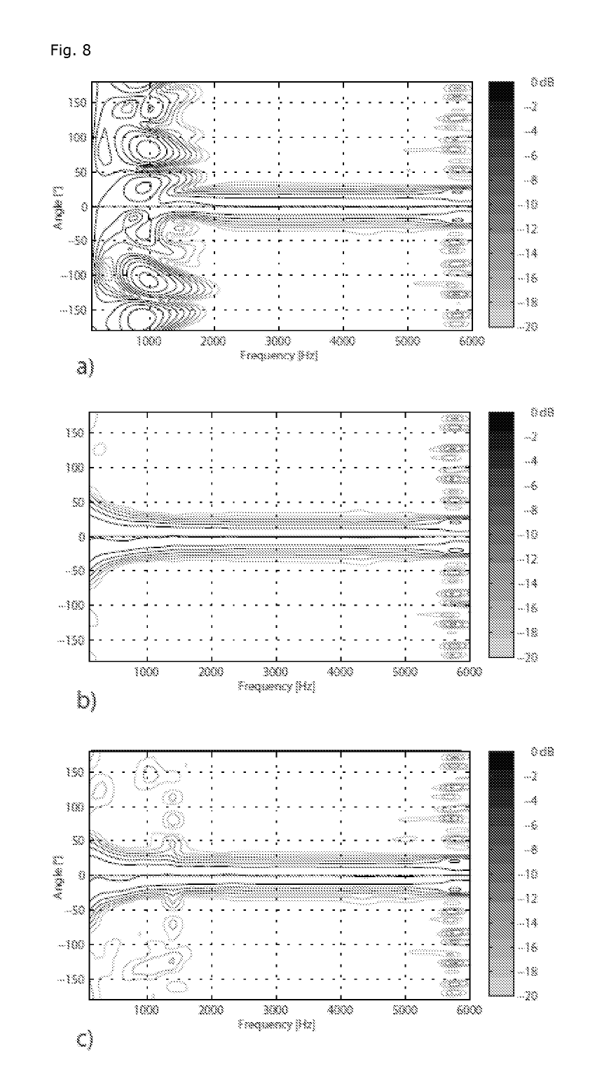

FIG. 8(a) shows the effect of a random variation in angular element placement of ±1°. It is seen that the angular variation highly affects the realized directivity pattern, especially at low frequencies, as indicated by reference numeral 3 in FIG. 8(a). The element weights, calculated from an ideal analytical expression, form the directivity pattern, through precise constructive/destructive interference between the array elements. Hence, when the position of the angular elements is altered, the interference patterns change which affects the realized directivity pattern. This is especially significant at low frequencies, where the beamforming technique is very sensitive to errors in the element weights.

FIG. 8(b) shows the effects of adding random variation of 0.5 dB amplitude to the transfer function, which the element weights are based upon. Again the effect (reference numeral 4) of the variation is seen mainly at low frequencies where the concept is most sensitive.

In FIG. 8(c) the two uncorrelated error sources described above are introduced in the simulation simultaneously. It is seen that the addition of noise to the transfer function has a positive effect on the response in comparison to when only the angular error is present. A physical explanation to this property is given as: The ideal transfer function from a single source is, as seen from FIG. 3, a very smooth ideal function. Thus, interference patterns with destructive dips approaching the ideal infinity attenuation are possible at points where the sound fields from two sources are 180° out of phase. When such ideal destructive interference patterns are slightly misplaced due to random source position, large errors follow in the formed directivity pattern. However, if the transfer function is not ideal (e.g. due to the addition of noise), such ideal interference patterns will not be present. Thereby, the resulting directivity pattern is inherently erroneous but also less sensitive to variation in the source position. The directivity pattern illustrated in FIG. 8(c) would presumably approximately represent a pattern obtained by a real physical embodiment of a 24 element loudspeaker unit according to the invention, as both of the above mentioned errors almost inevitably will be present in a real physical embodiment of the invention.

Experimental Results

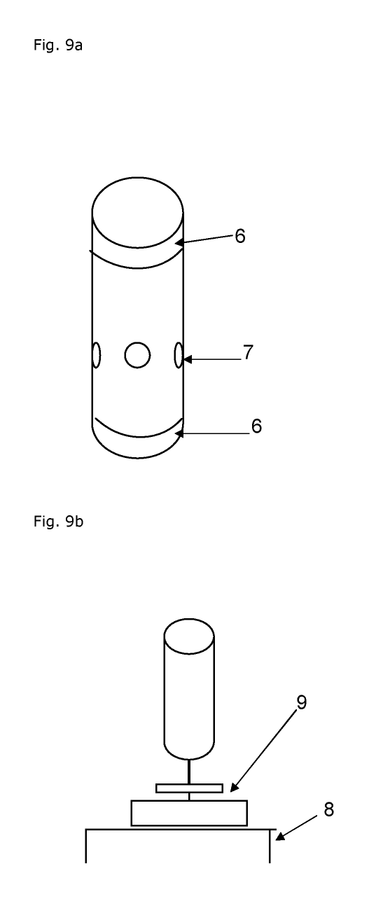

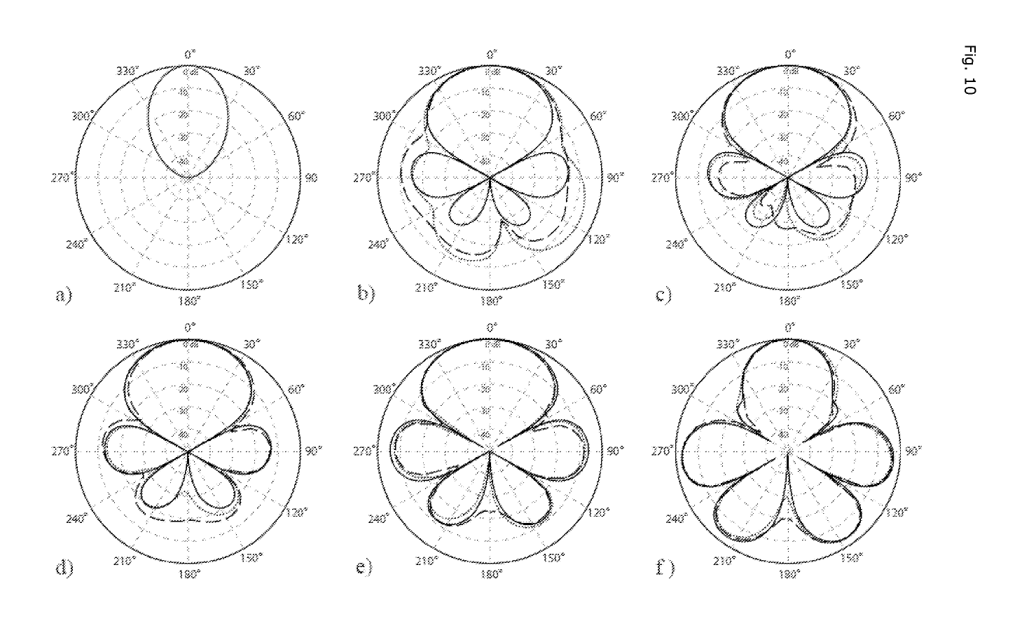

The concept of phase modes described above has been examined experimentally using a uniform circular array consisting of six equidistant loudspeaker drivers. The objective of the experiments presented in this section has been to verify the applicability of the concept of phase modes as a beamforming method. A small scale model was implemented primarily in order to verify the theory and simulations. In order to be able to reproduce the range of directivity patterns described previously, a larger number of loudspeakers should be used, for instance four times as many loudspeakers as in the small scale model described in this section. However, in order to examine the aspect of frequency invariance, a single predefined directivity pattern was utilized as target. The directivity target is shown in FIG. 10(a), which could not be expected to be perfectly reproduced with the implemented small scale model. A photo of this model is shown in FIG. 9(a) and a photo of the measurement setup for the experimental study in an anechoic room is shown in FIG. 9(b).

As shown in FIG. 9(a), the array elements 7 were mounted in a cylindrical baffle 5 having in this embodiment a length of 630 mm and closed at each longitudinal end by an end plate 6. The array elements consisted of six 2″ “full-range” loudspeaker drivers mounted in the hollow PVC cylinder with a wall thickness of 10 mm and an outer diameter of 200 mm, providing a sound hard baffle for the configuration. The baffle was closed at each end by a piece of solid wood 6. The drivers were chosen due to the directional properties, providing hemispheric radiation in the frequency interval of concern. The model was handcrafted by the inventors and without access to a CNC router. A directivity pattern has been measured in a large anechoic room that provides a good approximation to free-field conditions down to 50 Hz. In all cases, a Brüel & Kjaer (B&K) Pulse analyzer of type 3560 in FFT mode was used together with a free-field microphone B&K type 4091. The loudspeaker array was placed on a turntable B&K type 5960, reference numeral 9 in FIG. 9(b), which was placed on a support 8 being anchored to the ground of the room about 3 m below the support. A total of 72 measurements were conducted in the horizontal plane corresponding to a resolution of 5°. The distance from the cylindrical baffle centre to the measurement microphone (observation point) was approximately r=3.5 m. The measurement setup is shown in FIG. 9(b).

Pure tone signals were processed by off-line filtering and played back using a PC. The specific directivity pattern, used as reference in the experiments, was determined at five frequencies 500, 700, 1000, 1400 and 2000 Hz. Two different approaches for determining the weights of each array element were applied: In the first approach the sound field transfer function g(φ, r, φₙ, f) was simulated using the theory presented above, while in the second approach the transfer function was measured in a large anechoic room for each array element and applied. These two cases will be referred to in the following as gₛᵢₘ and gₘₑₐₛ, respectively. The experimental results are shown in FIG. 10 for both cases together with the predicted directivity for the configuration under test. It is seen in general that measurement results with gₘₑₐₛ agree fairly well with the simulations at 1000, 1400 and 2000 Hz, while larger deviations are found in the results obtained by applying gₛᵢₘ. This is most pronounced for the two back lobes in the region 120° to 240°, which are resolved less accurately compared to the predicted results and measurements with gₘₑₐₛ. At 500 and 700 Hz, the experimental reproduction reveals significant deviations from the predicted directivities. At 500 Hz, results obtained for both gₛᵢₘ and gₘₑₐₛ agrees well in the half plane for the focus direction. Dissimilarities in the side lobes are present in the remaining plane of up to around 30 dB. At 700 Hz both back lobes are significantly deviating for gₛᵢₘ, whereas gₘₑₐₛ almost resolves the one located at 200° to 220°.

Discussion of Results Obtained with the Small Scale Embodiment of the Invention

Comparing the measured results reveals significant differences between measurements obtained with gₛᵢₘ and gₘₑₐₛ, respectively. It is apparent that better performance is obtained when the utilized element weights are determined by the measured transfer function for the physical array structure under test, rather than an ideal simulation. When the weights are determined using the ideal simulated transfer function, this evidently implies that deviations from the actual physical sound field will occur. This corresponds to an error imposed on g(φ, r, φₙ, f) and the performance is getting worse, as expected. However, this is mainly found for the side and back lobes, whereas the main lobe is generally well reproduced, at least above 500 Hz.

Evaluating frequency invariant reproduction of a specific beam pattern is a rather difficult task considering only six elements. However, the results presented in FIG. 10 do indicate that the embodiment of the invention shown in FIGS. 9(a) and 9(b) is able to provide a directivity pattern that at least to some extent corresponds to the target directivity pattern, although it would be advantageous to use a larger number of loudspeaker drivers than the six used in the described embodiment. The directivity pattern is almost maintained for the measurements in a octave from 700 Hz to 1400 Hz. (c) to (e) in FIG. 10. At 2000 Hz, (f) in FIG. 10, the shape is distorted, as the side and back lobes become comparable to the main lobe in terms of beam width. Both measurements are very similar to the predicted pattern, which indicates that the upper frequency limitation of the beamforming method, concerning frequency invariance, is reached. In accordance with the spatial sampling criterion, 8 sources are required at 2000 Hz.

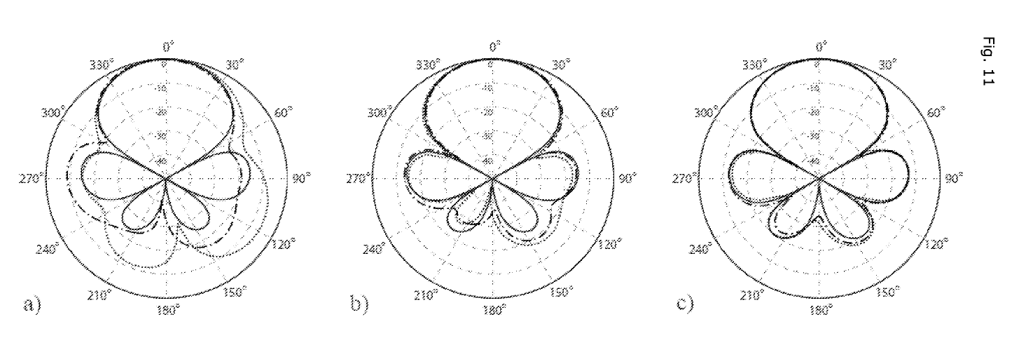

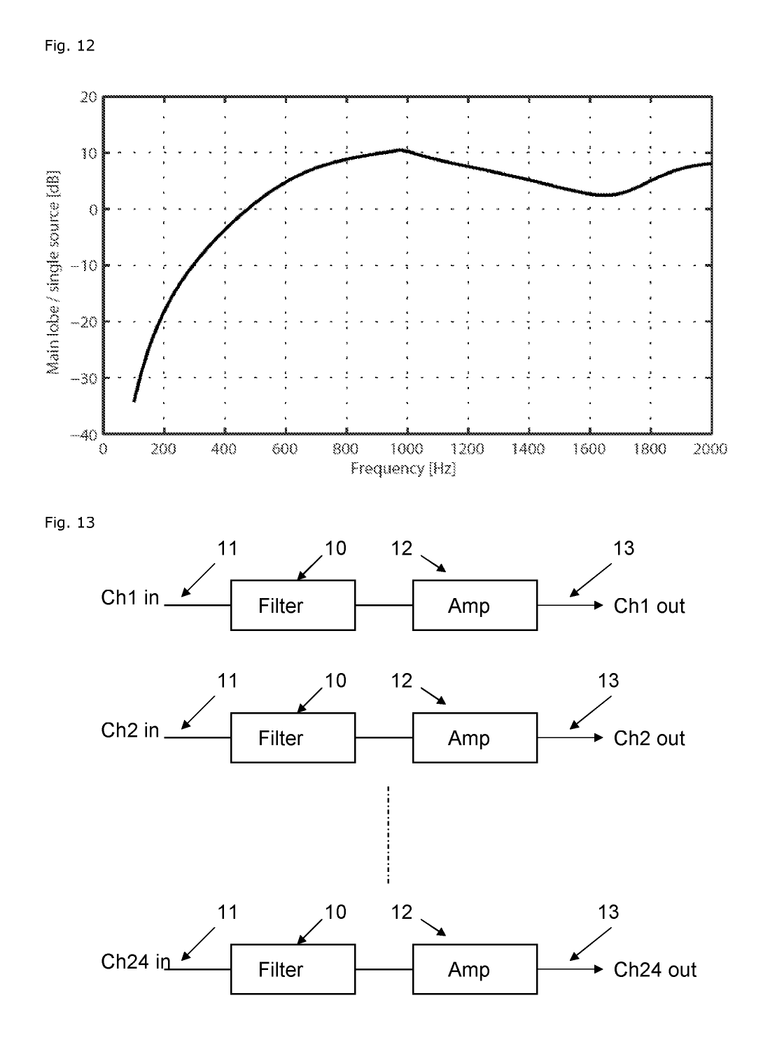

Inaccuracies in the practical implementation are inevitable and are seen to affect the experimental results. This is further aggravated when a hand-made model is under consideration. In the above section on the introduction of errors in the simulation it was shown that severe side lobes occur at low frequencies when introducing a random error in the angular placement of the array elements. The measurements below 1400 Hz seem to reveal a consistent error around 90° to 180° where the side lobes are not resolved properly. Presumably, these errors are associated with tolerances in the handcrafted small scale model with respect to the actual positioning of elements comprising a circular array. Individual differences in the resulting directivities measured using gₛᵢₘ and gₘₑₐₛ reveal whether the errors may be attributed to deviations from the physical sound field. However, the errors are found also when applying the measured transfer function, which must contribute with a somewhat more realistic representation of the sound field. This suggests that the requirement of a cylindrical array of equidistant elements is not perfectly met. In order to support this hypothesis, a simulation of a similar setup was performed with a random angular error imposed on all elements except at focus direction. The errors imposed on the angular position is within the range of ±4° and maintained over frequency. The results are shown in FIG. 11. It is found that the resulting type of behavior of the array performance agrees well with the patterns obtained in the experimental results. Only the three lowest frequencies are compared, since insignificant deviations are only found at 1400 and 2000 Hz, in agreement with the results in FIG. 10. The break-down of the beamforming method seen at 500 Hz is believed to be attributed to this type of positioning errors. This is further substantiated by considering the error sensitivity, similarly as done in the preceding sections. The sensitivity is shown in FIG. 12 and reveals that no problems due to the sensitivity will occur around 500 Hz.

The weights determined for each of the six elements are calculated for focus direction equal to the angular orientation of an element. It is apparent that the resolution of the focus direction heavily depends on the number of elements implemented. The directivity patterns presented in FIG. 10 are calculated for focus direction in front of element n=0. When focus direction is directly in between the angular orientation of two adjacent array elements, the beam pattern deviates from the target by assuming a distorted yet symmetrical pattern. Outside these angles, asymmetry occurs in the side lobes. The resolution is restricted to N focus directions with angular values φₙ (see (8)) when only six elements are included. Better resolution is expected for a full scale model comprising for instance 24 elements.

It is important to apply a control scheme for the number of active elements in the beamforming process that can maintain performance at low frequencies. The high sensitivity found here, is due to the interaction between low frequency excitation and a large density of array elements (relative to the wavelength of sound at low frequencies). A solution would be to reduce the number of loudspeakers contributing to the beamforming, for instance by a factor of two, below a specific frequency limit.

Conclusions

From the simulated results it has been demonstrated that it is possible to realize the desired directivity patterns across a frequency range from 500 to 4000 Hz applying 24 sources on a 0.15 m radius uniform circular array. However, it was also seen that using phase modes to control the beamforming introduces high sensitivity towards element weight errors at low frequencies.

A small scale practical embodiment of the invention comprising six 2″ “full-range” loudspeaker drivers mounted in a 0.1 m radius circular array has been implemented as described above. Even though it was not possible to realize the target directivities with six sources, the measurements obtained using the small scale embodiment showed very good agreement between measurements and the expected results from the simulations at 1000 to 2000 Hz. Significant deviations in the low frequency range 500 to 700 Hz might be attributed to production inaccuracies.

From these results it is concluded that the target directivity patterns can be realized with a practical 24 element array mounted on a 0.15 m radius circular array in the high range of the frequency range of interest. By plotting the ratio of the maximal sound pressure at the main lobe of the array to the on-axis pressure from a corresponding single source, a very large reduction in sound pressure was seen at low frequencies. From these results, problems due to high weight error sensitivity are expected below approximately 1700 Hz in the practical 24 element array.

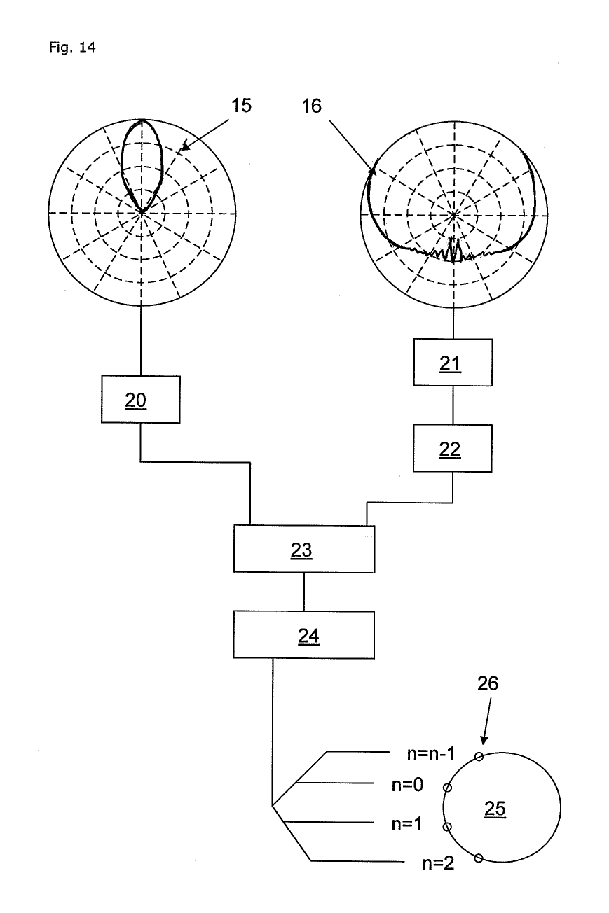

FIGS. 13 and 14 illustrate a specific embodiment of the circular loudspeaker array with controllable directivity according to the present invention. Referring to FIG. 13, this embodiment of the invention comprises a plurality of separate filters 10 receiving input signals from respective input channels and providing filtered output signals to corresponding power amplifiers 12 for each individual loudspeaker driver. The determination of each individual filter characteristic according to one specific embodiment of a method for controlling the loudspeaker array with controllable directivity according to the invention is illustrated with reference to FIG. 14, in which reference numeral 14 summarizes the calculations that are according to this embodiment needed in order to determine the individual filter characteristic of the filters 10 shown in FIG. 13. The procedure outlined at reference numeral 14 is a beamforming method for a single frequency response which determines the source weights necessary to generate the desired directivity at a single frequency. This procedure is repeated over the frequency interval of concern, and one filter per source (loudspeaker driver) is constructed to implement the source weights across frequency. By the procedure outlined in FIG. 14, essentially the desired directivity 15 is compared with the directivity 16 of the specific loudspeaker driver of the array using the basic compensation concept that a directivity is approximated by adjusting the response from each source “g( . . . )” by the weight “Wn”, as is seen in (9).

Both the desired directivity 15 and the directivity 16 of the specific source are decomposed into p harmonics in the respective steps 20 and 21. Here, (10), describing target directivity decomposed in circular harmonics, and (11), describing target harmonic strength calculated using DFT, may be used.

For the directivity 16 of the source, a summation of array element contributions to the p'th harmonic of the unweighted array is determined in step 22, after which harmonic weights are calculated as the ratio of desired harmonic strength and the harmonic strength of the unweighted array (step 23 where weightₚ=(desired harmonic strength/source harmonic strength). Here (12), describing that a weighting function may be regarded as a 2pi periodic function which can be decomposed into weight harmonics, (13), which describes target harmonic determined from transfer function and weight harmonic, and (15), describing weight harmonic strength determined from target harmonic strength and transfer function harmonic strength, may be used.

After this the sourceweight(n) is calculated through a summation of harmonic weights at source positions (step 24 where sourceweight(n)=sum over harmonics of weightₚ(φₙ)). Here (16), describing source weights determined by summation of weight harmonics at angular source position, may be used.

FIG. 14 illustrates a procedure determining the source weights necessary to generate the desired directivity at a single frequency. It is repeated over the frequency interval of concern, and one filter is constructed per source to implement the source weights across frequency.

These calculations result in the weights for each source (loudspeaker) 26 in the array 25 at the specific frequency where the shown source directivity 16 applies. Once the weights have been calculated for each frequency of interest, the complete frequency response of each individual filter 10 implementing the source weights as a function of frequency can be constructed.

These expressions have already been given in the preceding paragraphs.

Alternative methods for determining the filter characteristics may also be used without departing from the scope of the invention. In practice it would also be possible to avoid measuring the sound source directivities and to decompose these in circular harmonics. Instead it is possible to measure or calculate the transfer function g(φ, r, φₙ, f) between each individual source and a single observation point. For each circular harmonic, this transfer function is provided with a phase change corresponding to the position of the particular sound source in the array for the specific circular harmonic. This determines how much the individual source contributes to the circular harmonic in the observation point. Summing these contributions from each source results in an indication of how much the unweighted array excites each individual circular harmonic. This result is subsequently used to determine the weights based on how the array itself excites the circular harmonics and how they have to be excited in order to obtain the target directivity of the array.

It should be noted that the control method for providing the weights for each sound source according to the invention only requires that the sources be placed uniformly in a circle. The design of the baffle has no consequence as it is only needed to know the transfer function of the sources in order to be able to control the array. The number of sources will depend on the radius of the array, which precision is desired and within which frequency interval the desired directivity is to be obtained.

1. A method for controlling the directivity of a sound-emitting device, the method comprising:
(i) providing an array consisting of a plurality of sound sources each driven by an individual power amplifier;
(ii) for each of said plurality of sound sources providing a separate filter, the output signal of which is provided to the corresponding power amplifier;
(iii) at a specific frequency choosing a desired directivity;
(iv) at said specific frequency determining the directivity of each of said sound sources;
(v) at said specific frequency decomposing the desired directivity into p harmonics;
(vi) at said specific frequency decomposing the sound source directivity for each sound source of the array into p harmonics;
(vii) at said specific frequency summing the sound source contributions to the p'th harmonic of the unweighted array;
(viii) at said specific frequency calculating a weightₚ as the ratio between the desired harmonic strength and the harmonic strength of the unweighted array;
(ix) at said specific frequency calculating the source weights through a summation of harmonic weights at source positions, thereby arriving at the weights for each sound source in the array at that specific frequency where the source directivity applies;
(x) repeating the above steps (iii) through (ix) for each desired frequency of the frequency interval of interest, whereby the coefficients of each separate filter for each of the sound sources are determined;
(xi) constructing the required number of separate filters based on the coefficients determined under (x) above.

2. A sound-emitting device with controllable directivity comprising a plurality of sound sources distributed over the surface of a body, each of said sound sources being driven by a separate power amplifier, the input terminal of which is provided with the output signal from a corresponding filter constructed in accordance with steps (iii)-(xi) of claim 1, such that the frequency response of each individual sound source can be controlled, where each filter is provided with an input signal corresponding to a plurality of input channels Ch₁, Ch₂ . . . Ch_{N}.

3. A sound-emitting device according to claim 2, wherein said body is a cylindrical body provided with end pieces at either longitudinal end.

4. A sound-emitting device according to claim 2, wherein said sound sources are uniformly distributed over a circular path on the surface of the body.

5. A sound-emitting device according to claim 2, wherein said surface of the body is substantially rigid.

6. A sound-emitting device according to claim 2, wherein the number of sound sources is 6.

7. A sound-emitting device according to claim 2, wherein the number of sound sources is 24.

8. A sound-emitting device according to claim 2, wherein each of the filters have filter characteristics that are determined according to the method of claim 1.
